(19) United States
(12) Patent Application Publication
(10) Pub. No.: US 2013/0022211 A1
(43) Pub. Date: Jan. 24, 2013

(54) WIRELESSLY TRIGGERED VOICE ALTERING AMPLIFICATION SYSTEM

(71) Applicants: Ilissa Brooke Schild, Boston, MA (US); Paul Franzosa, Arlington, MA (US); Suzanne Wasserman, Winchester, MA (US); Tracy Wilson, Medford, MA (US); Roxana Chiu, Boston, MA (US)

(72) Inventors: Ilissa Brooke Schild, Boston, MA (US); Paul Franzosa, Arlington, MA (US); Suzanne Wasserman, Winchester, MA (US); Tracy Wilson, Medford, MA (US); Roxana Chiu, Boston, MA (US)

(73) Assignee: FIRST ACT, INC., Boston, MA (US)

(21) Appl. No.: 13/465,581

(22) Filed: May 7, 2012

Related U.S. Application Data
(60) Provisional application No. 61/510,902, filed on Jul. 22, 2011.

(51) Int. Cl. H03G 3/00; G06K 7/01; H03F 99/00

(52) U.S. Cl. 381/61; 381/120

(57) ABSTRACT

A system and method for wirelessly triggering an amplification system are disclosed. In one example, the system for wirelessly triggering the amplification comprises at least one wireless tag, the at least one wireless tag having unique identification (ID) information and an amplification system configured to receive audio signals. Further, the amplification system comprises a wireless reader configured to receive and determine the ID information from the at least one wireless tag, and a processor configured to associate at least one sound effect with the ID information received from the at least one wireless tag and to modify the audio signals to include the at least one sound effect.

### RELATED APPLICATIONS

This application claims priority under 35 U.S.C. §119(e) to U.S. Provisional Application Ser. No. 61/510,902 entitled “RFID TRIGGERED VOICE ALTERING AMPLIFICATION SYSTEM,” filed on Jul. 22, 2011, which is hereby incorporated herein by reference in its entirety.

### BACKGROUND

1. Applicable Field

The present invention related to the field of music and entertainment, and more specifically to an interactive voice amplification system and method.

2. Related Art

Various sound augmentation methods and systems may be able to augment the human voice to deliver various desired sound effects. For example, singers often use vocal tuning or pitch correction to disguise off-key inaccuracies in vocal tracks. Other voice effects, such as robotic sounds effects, are used in popular music to produce diverse range of sounds. Typically, the sound and voice effects are used to augment or modify the voice tracks after the sound tracks have been recorded.

### SUMMARY

Various entertainment systems on the market provide simulated performing experiences that enable users to imagine being live performers in front of an audience. For example, video games may include controllers modeled after musical instruments such as guitars and microphones. Similarly, popular karaoke systems provide forms of interactive entertainment in which singers sing along with recorded music using a microphone, while the lyrics to songs are displayed on a screen. Further, various toys provide the ability to modify a person's voice to provide entertainment.

As discussed above, various sounds and voice effects may be used by professional performers to augment human voices to add artistic license to the sound or to correct or disguise off-key inaccuracies. It is appreciated that having the professional sound and voice effects to be delivered at the same time as the voice or sound projected may be desired. It may also be desirable to have the simulated performance systems to take advantage of the benefits of augmentation techniques to produce professional sound techniques.

Therefore, according to one embodiment a system and method for triggering sound altering amplification is disclosed. According to various embodiments, the system includes an amplification system and various wireless identification (ID) tags. The wireless ID tags are encoded with unique signatures, which when received by the amplification system, cause the amplification system to produce different sound or voice effects. The system allows the singer to quickly change between different voice and sound effects without pressing buttons or selecting different options. The wireless ID tags may be incorporated into different accessories that may enhance the feel of the simulated performance. In addition, the amplification system may be able to receive any number of unique signatures resulting in any number of voice or sound effects to be produced.

According to one embodiment, a wirelessly triggered amplification system is disclosed. The wirelessly triggered amplification system comprises at least one wireless tag, the at least one wireless tag having unique identification (ID) information and an amplification system configured to receive audio signals. Further, the amplification system comprises a wireless reader configured to receive and determine the ID information from the at least one wireless tag, and a processor configured to associate at least one sound effect with the ID information received from the at least one wireless tag and to modify the audio signals to include the at least one sound effect.

In one example, the system further includes a microphone configured to receive the audio signals. In another example, the system further includes a speaker configured to output at least one of the audio signal and the audio signals modified to include the at least one sound effect. In the system, the wireless reader is a RFID reader configured to transmit an interrogating signal to the at least one wireless tag. In addition, the at least one wireless tag may comprise a RFID tag. Further, the RFID tag may comprise a passive tag including an induced voltage antenna coil, configured to transmit the ID information in response to receiving a signal from the RFID reader. Alternatively, the RFID tag may comprise an active tag configured to actively transmit the ID information to the wireless reader.

In another example, the system further includes an audio input configured to receive audio signals from a portable music player, wherein the amplification system is configured to mix the received audio signals from the portable music player with the audio signals modified with the at least one sound effect. In addition, the processor further may comprise a memory configured to store the at least one sound effect. In the system, the amplification system may comprise a microphone shape and the at least one wireless tag comprise at least one accessory.

According to another aspect, a method of wirelessly triggering an amplification system is disclosed. The method comprises receiving, via a wireless reader, at least one wireless signal from at least one wireless tag, receiving audio signals by the amplification system, determining ID information from the wireless signal associated with the at least one wireless tag, and determining at least one sound effect associated with the ID information received from the at least one wireless tag. In addition, the method further comprises modifying the received audio signals to include the at least one sound effect, and outputting the modified audio signals via the amplification system.

In the method, receiving the at least one wireless signal from the at least one wireless tag further comprises receiving a first wireless signal from a first wireless tag and determining a first ID information from the first wireless signal, and determining a first sound effect associated with the first ID information and modifying the audio signals to include the first sound effect.

In one example, method further comprises receiving a reset input from a user via the amplification system, and outputting the audio signals as received by the amplification system without modifying the audio signals. In the method, receiving the at least one wireless signal from the at least one wireless tag may further comprises receiving a second wireless signal from a second wireless tag and determining a second ID information from the second wireless signal, and determining a second sound effect associated with the second ID information and modifying the audio signals to include the second sound effect. In the method, receiving the at least one wireless signal from the at least one wireless tag may further comprise receiving the first wireless signal from the first wireless tag and determining the first ID information from the first wireless signal, and determining a third sound effect in response to determining the second ID information followed by the first ID information and modifying the audio signals to include the third sound effect.

In another example, the method further comprises receiving a feature input from a user via the amplification system associated with at least one feature sound, and outputting the at least one feature sound via the amplification system. In addition, the method may further include transmitting, by the wireless reader, an interrogating signal to the at least one wireless tag. Further, the method may also include transmitting by the at least one wireless tag, the ID information, in response to receiving the interrogating signal from the wireless reader. In one example, the method further includes actively transmitting, by the at least one wireless tag, the ID information to the wireless reader. In another example, the method further includes

receiving, via an audio input, audio signals from a portable music player and mixing the received audio signals from the portable music player with the modified audio signals having the at least one sound effect.

Still other aspects, embodiments, and advantages of these exemplary aspects and embodiments, are discussed in detail below. Any embodiment disclosed herein may be combined with any other embodiment in any manner consistent with at least one of the objects, aims, and needs disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described in connection with the embodiment may be included in at least one embodiment. The appearances of such terms herein are not necessarily all referring to the same embodiment. The accompanying drawings are included to provide illustration and a further understanding of the various aspects and embodiments, and are incorporated in and constitute a part of this specification. The drawings, together with the remainder of the specification, serve to explain principles and operations of the described and claimed aspects and embodiments.

### BRIEF DESCRIPTION OF THE DRAWINGS

Further features and advantages as well as the structure and operation of various embodiments are described in detail below with reference to the accompanying drawings. In the drawings, like reference numerals indicate like or functionally similar elements.

Additionally, the left-most one or two digits of a reference numeral identifies the drawing in which the reference numeral first appears.

FIG. 1 is an example of a wirelessly triggered voice altering amplification system, according to one embodiment;

FIG. 2 is an example of a wirelessly triggered voice altering amplification system, according to one embodiment; and

FIG. 3 is an example of the amplification system, according to one embodiment.

### DETAILED DESCRIPTION

A system and method for triggering sound altering amplification is disclosed herein. According to one aspect, an amplification system or device that includes a microphone and a speaker built-in to the amplification system is disclosed. The amplification system receives sound or voice signals, via the microphone, and identification information via a wireless reader from one or more wireless tags. The identification information is matched to one or more sound effects and the amplification system alters the received voice signals or sound signals based on the sound effects. The altered voice signals are output by the speaker. One or more wireless tags, each having a unique signature, can transmit a signal to the reader, which can identify the unique signature and trigger different sound effects to be output or played by the speaker. Various combinations of tags may be used to render unique sound effects.

Aspects disclosed herein, which are in accordance with various embodiments, are not limited in their application to the details of construction and the arrangement of components set forth in the following description or illustrated in the drawings. These aspects are capable of assuming other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments. Moreover, the systems described herein may be configured to include or exclude any of the functions discussed herein.

Thus, the embodiments of the present invention are not limited to a specific function or set of functions. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items.

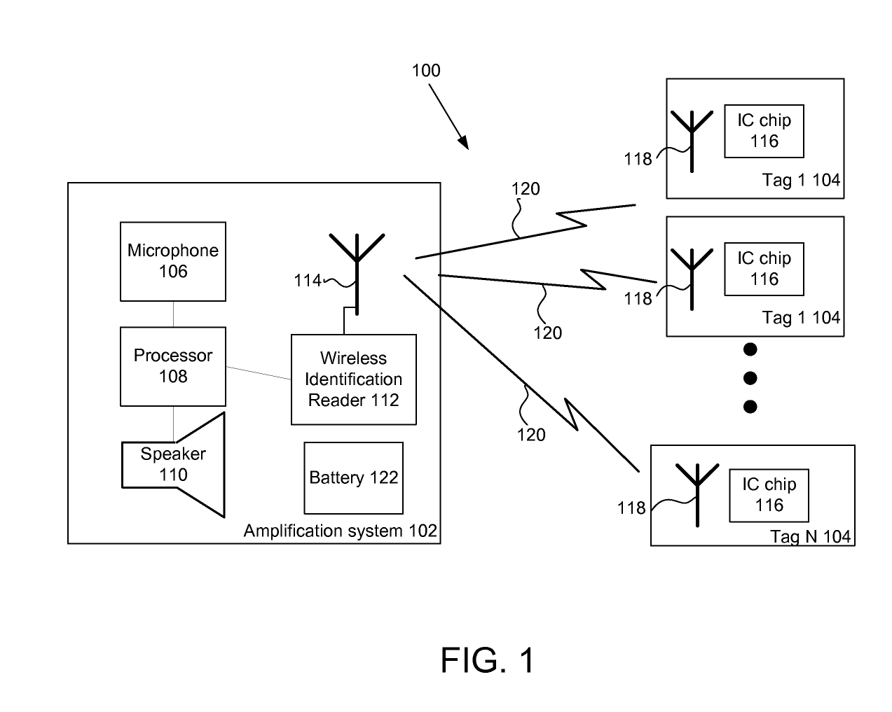

FIG. 1 shows one example of a wirelessly triggered voice altering amplification system 100 according to various embodiments. The system 100 includes an amplification system 102 and one or more tags 104 which are configured to trigger various sound effects (e.g. voice effects) in the amplification system 102. The amplification system 102 includes a microphone 106, a processor 108, a speaker 110, a wireless identification reader 112, an antenna 114 and a battery 122, which may be coupled to and provide power to all the components of the amplification system 102. Each of the wireless tags 104 further includes an IC chip 116 and an antenna 118 configured to receive and transmit identification (ID) information 120 to the wireless identification reader 112.

In one example implementation of the system, a user sings into the amplification system 102, which receives the user's voice via the microphone 106, processes the received audio signals, and outputs or plays the sounds via the speaker 110. When the user brings one of the wireless tags 104 in proximity to the amplification system 102 a unique electronic signal or ID is transmitted from the wireless tag 104 to the amplification system 102. The ID is decoded by the wireless identification reader 112 and output to the processor 108, which associates the ID with a particular voice or sound effect. The processor 108 alters the audio signals received from the microphone 106 based on the associated voice effect and outputs the altered sound to the speaker 110 to be broadcast. In one embodiment, elements of the amplification system 102 shown in FIG. 1 are housed within a microphone that can be used by the user to modify their voice.

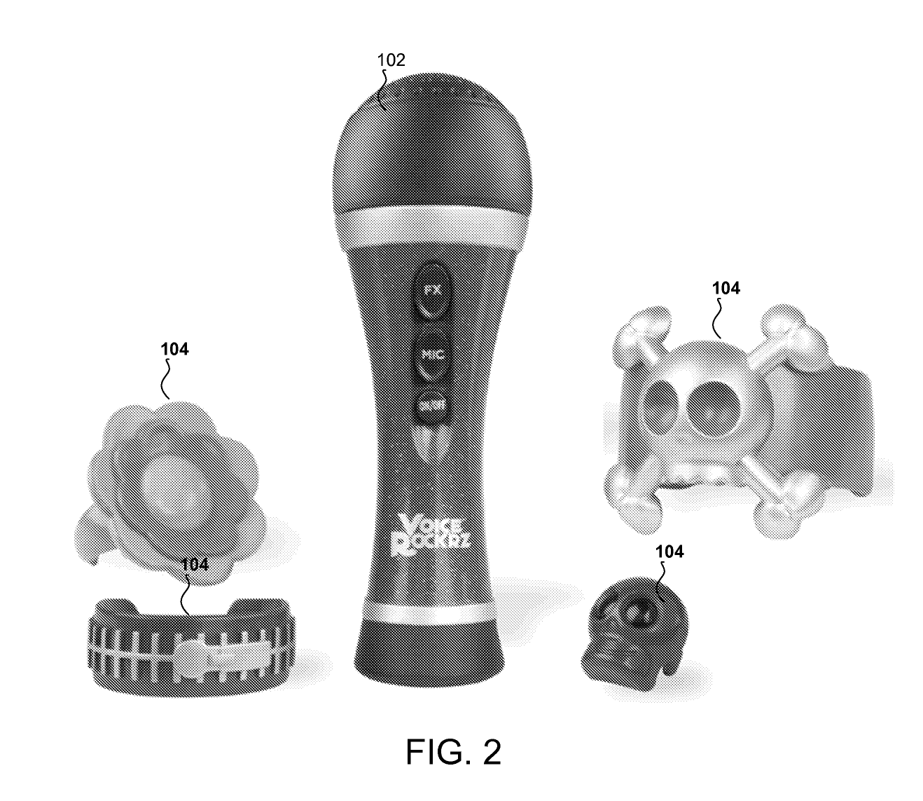

In particular, FIG. 2 shows one embodiment of the amplification system 102 and the wireless tags 104. As shown, the amplification system 102 can be housed within as a dynamic “on-stage” microphone, which includes a handle and a mouth piece. The amplification system 102 further includes buttons on the side of the microphone handle. The buttons may be included in the amplification system 102 and may provide for “on” and “off” functionality, reset functionality and additional sound effect functionality. However, it is contemplated that the amplification system 102 may be housed within different shapes. For example, the amplification system may be shaped as a retro or vintage microphone, or a headset.

As shown, the wireless tags are housed into various accessories including rings and bracelets. However, it is appreciated that the wireless tags may also be different functional or decorative articles. Also, it should be appreciated that amplification system 102 may be housed in different types of devices, such as a guitar amplifier, or other systems that are capable of receiving audio signals and producing sound. The user sings into the “on-stage” microphone which amplifies and projects the sounds. In one example, the user may activate various sound effects, as described below, by tapping one of the accessories to a designated portion of the “on stage” microphone. In various embodiments, one or more wireless tags may be incorporated into a single accessory. In addition, a single wireless tag may also provide more than one unique code.

Referring again to FIG. 1, according to various embodiments, the amplification system 102 includes the wireless identification reader 112 that is configured to receive information 120 from one or more wireless tags 104. The wireless identification reader 112 is configured to wirelessly receive and decode the ID information 120 encoded on the wireless tag 104. The wireless identification reader 112 may use any method of short range communication, such as Radio Frequency Identification (RFID), Magnetic Field Identification (MFID), or Bluetooth or any other standard or method of short range communication. In one embodiment, the wireless identification reader 112 is configured to transmit and receive information over a short distance without having line of sight between the tag and the reader. In embodiments described below, the wireless reader comprises a RFID reader and the wireless tag comprises a RFID tag, however it should be appreciated that the system may be implemented using any short range communication protocol.

In various embodiments, the RFID reader 112 includes a transmitter and receiver and communicates information 120 via the antenna 114. The transmitter may transmit an interrogating signal to the RFID tag, which in response to receiving the interrogating signal may transmit to the RFID 112 reader identification information associated with the RFID tag 104. In addition, the RFID tag 104 may also transmit the information stored in a memory of the RFID tag 104. The receiver included in the RFID reader can be used to convert signals received from the RFID tag 104 into messages, unique signatures, or other electronic signals, which can then be communicated to the processor. The signals from the reader and to the reader may be transmitted through the antenna 114. One example of the RFID reader 112 includes a multi-functional reader W55MID50 available from Nuvoton Technology Corporation, Hsinchu Science Park, Taiwan.

As shown in FIG. 1, the RFID tags 104 include the antenna 118 coupled to the IC chip 116. Depending on the type of tag used within the system 100, the IC chip 116 may include a transmitter, a receiver, a non-volatile memory, and a battery. The type of antenna 118 used may also be dependent on the type of tag used. In various examples, passive RFID tags, as discussed below, include an induced voltage antenna coil for operation, which is rectified to provide a voltage source for the IC chip 116. The induced coil antenna may comprise any shape or pattern. The memory may be configured to store a unique ID and, in some examples, additional information. The IC chip 116 may be further configured to process received information, as well as modulate and demodulate the radio-frequency signal. One example of the RFID tag includes the W55MID35 Transponder available from Nuvoton Technology Corporation, Hsinchu Science Park, Taiwan.

According to various examples, the RFID tags 104 used within the system 100 may be passive, active or semi-passive. In some examples, passive tags do not include a battery and use radio energy transmitted by the RFID reader to power the tag, when the tag comes within close proximity to the RFID reader. Therefore, these passive tags only transmit the ID information in response to receiving a signal from the RFID reader. In one example, passive tags, rather than transmitting a signal, vary the reflection of the signal from the reader. Because the passive tags rely on the RFID reader for power, these passive tags, in some examples, operate in close range and need to be brought in close proximity to the RFID reader 112 to power and transmit information. In other embodiments, active tags may be used that may include an on-board battery that periodically transmits its ID signal.

Active tags, in some examples, include a transmitter and a receiver and may be able to operate over a longer range, for example 100 meters. In additional examples, semi-passive tags may be used that include a small battery on board and which may be activated when in the presence of the RFID reader 112. Similar to passive RFID tags, semi-passive do not include a transmitter and may be able to operate over a medium range, for example 10 meters. In some examples, the RFID reader may be able to simultaneously read multiple tags within a predetermined range of the RFID reader.

According to one example, the processor 108 receives the unique ID from the RFID tag 104 decoded by the RFID reader 112 and matches the unique ID with a particular sound effect. Any number of sound effects may be produced, including, but not limited to reverb, low pitch, super low pitch, super high pitch, hall or echo, chorus, distortion, flange, or robotic sound effect. In some examples, if the ID is not received from the ID tag 104, the processor 108 may not apply any sound effect to the sound received from the microphone 106.

In one example implementation, the ID received from Tag 1 may be associated with a first sound effect, for example a high pitch sound effect, which may be applied to the sound received from the microphone 106 to alter the sound and output the high pitch sound effect signal to the speaker 110. The ID received from Tag 2 may be associated with a second sound effect, for example an echo sound effect, which is applied to the sound received from the microphone 106 to alter the sound and output the echo sound signal to the speaker 110. Any number of IDs can be received from any number of wireless ID tags to produce any number of sound effects. In various examples, the combination of IDs received either simultaneously or one at a time from Tag 1 and Tag 2 may produce a different sound effect, for example a low pitch sound effect. For example, the ID from Tag 1 can be received followed by the ID from Tag 2, which may produce a third sound effect, for example a robotic voice sound effect. It is appreciated that any combination of sound effects may be produced as a result of any sequence of IDs from various wireless tags 104.

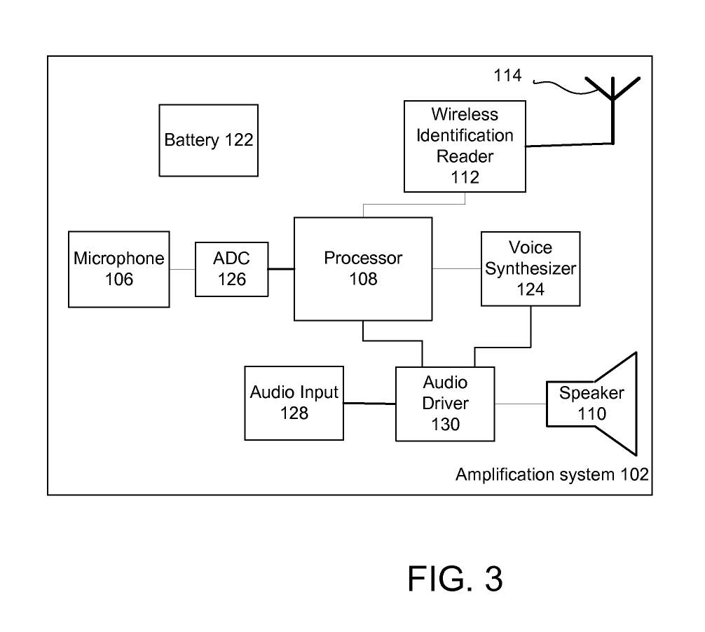

FIG. 3 shows a more detailed illustration of the amplification system 102 including a voice synthesizer 124, an Analog-to-Digital Converter (ADC) 126, an audio input 128 and an audio driver 130. The microphone 106 receives sounds, for example human voice, which are processed and output to the processor 108. The microphone 106 may be an acoustic-to-electric sensor configured to convert mechanical vibration of sound into an electrical signal. The microphone 106 may include additional components for receiving and processing sounds. In one example, the microphone 106 may produce an output that is provided to the ADC 126, which is configured to receive the analog sound signal and output a digital signal representing the received sound. For example, the ADC 126 may comprise a low cost serial 10-bits ADC with 8 individual input channels may be used available from Sonix Technology

Co., Ltd., Chupei City, Hsinchu, Taiwan.

The processor 108 may receive the output from the ADC 126 and provide an output to the speaker 110. The output to the speaker 110 may be unprocessed by the processor 108 or the output may be processed (e.g. filtered to remove noise or distortion) before being output to the speaker 110. The speaker 110 may include an electro-acoustic transducer that accurately reproduces sound in response to receiving the output from the processor 108 at the input of the speaker 110. In one example, the speaker 110 may be coupled to the audio driver 130, which may be configured to change the amplification levels (or gain) of the received sound signal.

In various examples, the processor 108 can utilize any number of digital sound synthesis techniques to apply the sound effects to the received sound, including but not limited to frequency modulation, amplitude modulation, filtering, phase distortion, subtractive synthesis, additive synthesis, changing sampling rate, or stretching. Any combination of software and hardware can be used to produce the desired sound effects. For example, the processor may include a built-in software melody synthesizer including a dual-tone melody and 8-channel wave-table melody. One example of a processor 108 includes a micro-controller based on DSP architecture available from Sonix Technology Co., Ltd., Chupei City, Hsinchu, Taiwan. One example of the implementation may include a voice synthesizer 124 used in combination with the processor 108. In one example, a one-channel voice synthesizer IC with PWM direct drive circuit may be used available from Sonix Technology Co., Ltd., Chupei City, Hsinchu, Taiwan.

The processor 108 may further include memory that may be used for storing data during operation of the amplification system 102. Thus, the memory may be a volatile, random access memory such as static random access memory (SRAM). The processor may also include a computer readable and writeable nonvolatile (non-transitory) storage medium (e.g. read only memory (ROM)) in which instructions are stored that define a program or other object that may be executed by the processor. The memory also may include information that is recorded, on or in, the medium, and this information may be processed by the processor during execution of the program.

The amplification system 102 may include additional features or controls. For example, the amplification system 102 may include a reset button, amplitude controls which change the sound level, additional sound effects, as well as one or more inputs/outputs. In one example, the reset button allows the user to remove any sound effects previously applied to the original sound received by the amplification system 102. For example, when the button is pressed by the user, the processor 108 may be configured to remove any sound effects previously applied to the original sound received from the microphone.

In some examples, the amplification system 102 may provide additional sound effects or featured preprogrammed and stored in the processor 108. For example, the processor 108 may include sound effects simulating applause, a drum roll, or background accompaniment sounds, for example different beats or melodies. These sounds may be stored in the memory of the processor 108. The features may be output by the speaker 110 in response to receiving an input from a user (e.g. user presses a feature button). In at least one example, the speaker 110 may repeatedly output a series of sound features (e.g. “cycle through”) in response to receiving the feature input from the user.

In an embodiment, the amplification system 102 may include various inputs and/or outputs. In one example, the amplification system 102 may provide for an audio input 128 (or “jack”) that allows the amplification system 102 to receive signals from a portable music device, such as an MP3 player. The audio input may allow for the user to stream music from the external MP3 player, which is output by the speaker 110. In one example, the audio input may include an auxiliary stereo input. The user can then sing along to the music played by the MP3 player and add any additional sound effects, as described above.

Having thus described several aspects of at least one embodiment of this invention, it is to be appreciated that various alterations, modifications, and improvements will readily occur to those skilled in the art. Such alterations, modifications, and improvements are intended to be part of this disclosure, and are intended to be within the scope of the invention. Accordingly, the foregoing description and drawings are by way of example only.

What is claimed is:

1. A wirelessly triggered amplification system comprising:
at least one wireless tag, the at least one wireless tag having unique identification (ID) information; and
an amplification system configured to receive audio signals, the amplification system comprising:
a wireless reader configured to receive and determine the ID information from the at least one wireless tag; and
a processor configured to associate at least one sound effect with the ID information received from the at least one wireless tag and to modify the audio signals to include the at least one sound effect.

2. The system of claim 1, further including a microphone configured to receive the audio signals.

3. The system of claim 1, further including a speaker configured to output at least one of the audio signal and the audio signals modified to include the at least one sound effect.

4. The system of claim 1, wherein the wireless reader is a RFID reader configured to transmit an interrogating signal to the at least one wireless tag.

5. The system of claim 4, wherein the at least one wireless tag is a RFID tag.

6. The system of claim 5, wherein the RFID tag is a passive tag including an induced voltage antenna coil, configured to transmit the ID information in response to receiving a signal from the RFID reader.

7. The system of claim 5, wherein the RFID tag is an active tag configured to actively transmit the ID information to the wireless reader.

8. The system of claim 1, further including an audio input configured to receive audio signals from a portable music player, wherein the amplification system is configured to mix the received audio signals from the portable music player with the modified audio signals with the at least one sound effect.

9. The system of claim 1, wherein the processor further comprises a memory configured to store the at least one sound effect.

10. The system of claim 1, wherein the amplification system comprises a microphone shape and the at least one wireless tag comprise at least one accessory.

11. A method of wirelessly triggering an amplification system, the method comprising:
receiving, via a wireless reader, at least one wireless signal from at least one wireless tag;
receiving audio signals by the amplification system;
determining ID information from the wireless signal associated with the at least one wireless tag;
determining at least one sound effect associated with the ID information received from the at least one wireless tag;
modifying the received audio signals to include the at least one sound effect; and
outputting the modified audio signals via the amplification system.

12. The method of claim 11, wherein receiving the at least one wireless signal from the at least one wireless tag further comprises:
receiving a first wireless signal from a first wireless tag and determining a first ID information from the first wireless signal; and
determining a first sound effect associated with the first ID information and modifying the audio signals based on the first sound effect.

13. The method of claim 12, further comprising:
receiving a reset input from a user via the amplification system; and
outputting the audio signals as received by the amplification system without modifying the audio signals.

14. The method of claim 13, wherein receiving the at least one wireless signal from the at least one wireless tag further comprises:
receiving a second wireless signal from a second wireless tag and determining a second ID information from the second wireless signal; and
determining a second sound effect associated with the second ID information and modifying the audio signals to include the second sound effect.

15. The method of claim 13, wherein receiving the at least one wireless signal from the at least one wireless tag further comprises:
receiving the first wireless signal from the first wireless tag and determining the first ID information from the first wireless signal; and
determining a third sound effect in response to determining the second ID information followed by the first ID information and modifying the audio signals to include the third sound effect.

16. The method of claim 11, further comprising:
receiving a feature input from a user via the amplification system associated with at least one feature sound; and
outputting the at least one feature sound via the amplification system.

17. The method of claim 11, further including transmitting, by the wireless reader, an interrogating signal to the at least one wireless tag.

18. The method of claim 17, further including transmitting by the at least one wireless tag, the ID information, in response to receiving the interrogating signal from the wireless reader.

19. The method of claim 11, further including actively transmitting, by the at least one wireless tag, the ID information to the wireless reader.

20. The method of claim 11, further including:
receiving, via an audio input, audio signals from a portable music player; and
mixing the received audio signals from the portable music player with the modified audio signals having the at least one sound effect.
